(19) United States
(12) Patent Application Publication
(10) Pub. No.: US 2014/0013868 A1
(43) Pub. Date: Jan. 16, 2014

(54) TEST FIXTURE WITH HAND SIMULATION FOR WIRELESS COMMUNICATION TERMINAL

(71) Applicant: Samsung Electronics Co., Ltd., Gyeonggi-do (KR)

(72) Inventors: Young-Hak SIN, Gyeonggi-do (KR); Jae-Bong CHUN, Gyeonggi-do (KR); Jeong-Hoon KIM, Gyeonggi-do (KR); Dong-Hwan KIM, Gyeonggi-do (KR); Austin KIM, Gyeonggi-do (KR); Jae-Ho LEE, Gyeonggi-do (KR); Gyu-Bok PARK, Gyeonggi-do (KR)

(21) Appl. No.: 13/909,277

(22) Filed: Jun. 4, 2013

(30) Foreign Application Priority Data
Jul. 16, 2012 (KR) 10-2012-0077281

(51) Int. Cl. G01R 29/08

(52) U.S. Cl. CPC G01R 29/0864
USPC 73/865.6

(57) ABSTRACT

A test fixture with hand simulation for securing a wireless terminal during a performance test is provided. The test fixture includes first and second dielectric parts adjustably spaced apart to adjust a distance of a housing space therebetween within which the wireless terminal is securable. The first and second dielectric parts simulating respective portions of a human hand holding the wireless terminal. The housing space is adjusted according to a size of the wireless terminal by adjusting a distance between portions of the first and second dielectric parts.

### CLAIM OF PRIORITY

This application claims priority under 35 U.S.C. §119(a) to a Korean Patent Application filed in the Korean Intellectual Property Office on Jul. 16, 2012 and assigned Serial No. 10-2012-0077281, the contents of which are herein incorporated by reference.

### BACKGROUND

1. Technical Field

The present disclosure relates generally to electromagnetic testing of wireless communication terminals. More particularly, it relates to a test fixture for securing a wireless communication terminal during an electromagnetic test, where the fixture simulates the presence of a user's hand holding the wireless terminal.

2. Description of the Related Art

In recent years, the use of mobile communication terminals such as smart phones and tablet PCs has proliferated among consumers. Considering the radio wave electromagnetic energy transmitted by such terminals and its effect on users, regulations on mobile communication terminals are strict.

Particularly, the Federal Communications Commission (FCC) has adopted a guide for an assessment of environmental impact of Radio Frequency (RF) radiation of wireless communication terminals (so called portable phones), and has stipulated local absorption limits to be applied to any portable transmission equipment. Stipulated limits of maximum allowable exposure are based on a quantitative exposure assessment criterion based on a Specific Absorption Rate (SAR), which is the standard of an RF energy absorption rate.

In the case where electromagnetic waves are irradiated into a human body, quantitative assessment of the electromagnetic waves is carried out through power measurement, electromagnetic field analysis, SAR measurement through animal experiments and the like. SAR refers to absorption power per unit mass absorbed by a living body as the living body is exposed to the electromagnetic field.

Commonly, a SAR measurement is actually difficult to perform in a direct measurement of a human body. Therefore, tests with human body simulation have been developed, which assesses SAR through power measurement within a so-called human body phantom. This phantom has RF absorption properties similar to those of a human body when the electromagnetic waves are irradiated into the human body phantom. For instance, a “head phantom” is for measuring impact that a wireless communication terminal makes on a head of a human body. A “hand phantom” is for measuring the performance (deterioration) of the terminal in an environment as if a user holds the terminal in his hand.

Particularly, a conventional hand phantom is formed to have, for example, a shape as if a hand of a human body holds a terminal. The hand phantom is filled with a liquid, mounts the terminal, and measures the performance of the terminal. A separate hand phantom is typically individually manufactured and used according to various shapes and sizes of terminals.

However, in the conventional hand phantom filled with liquid, a problem arises where, if it is used for a long time, the liquid within the hand phantom evaporates or leaks out. This may cause a large measurement error in the wireless terminal measurement. Further, manufacturing cost is high because many hand phantoms need to be manufactured suitably for communication terminals that are put on the market in various sizes and shapes.

### SUMMARY

One aspect of the present disclosure is to provide a hand phantom for securing a wireless communication terminal during electromagnetic performance testing, which is configured to secure terminals of varying sizes

A further aspect is to provide a hand phantom for testing a wireless communication terminal, in which it is realized to have the almost same condition as a hand of a human body and contribute to a reliable measurement of the performance of a wireless communication terminal.

Disclosed is a test fixture with hand simulation for securing a wireless terminal during a performance test. The test fixture includes first and second dielectric parts adjustably spaced apart to adjust a distance of a housing space therebetween within which the wireless terminal is securable. The first and second dielectric parts simulating respective portions of a human hand holding the wireless terminal. The housing space is adjusted according to a size of the wireless terminal by adjusting a distance between portions of the first and second dielectric parts.

In an embodiment, the test fixture may include a first side bar of a predetermined length; first cross bars oriented transversely to the first side bar and disposed at a lower surface thereof; a second side bar of a predetermined length; and second cross bars oriented transversely to the second side bar and disposed at a lower surface thereof, where the first and second cross bars are reciprocally guided to provide the housing space.

In embodiments, a low dielectric constant spacer may be provide to simulate an air gap between a user's palm and the wireless terminal in a hand held state.

### BRIEF DESCRIPTION OF THE DRAWINGS

The above features and advantages of the present invention will become more apparent from the following detailed description when taken in conjunction with the accompanying drawings in which:

FIG. 1 is an exploded perspective view illustrating a hand phantom according to a desirable exemplary embodiment of the present invention;

FIG. 2 is a rear perspective diagram illustrating a combined state of the hand phantom of FIG. 1 according to the present invention;

FIG. 3 is a diagram illustrating a state in which a wireless communication terminal for performance test is mounted on the hand phantom of FIG. 1 according to the present invention;

FIGS. 4A and 4B are cross-sectional views illustrating respective shapes of an assistance dielectric part according to exemplary embodiments;

FIG. 5 is an exploded perspective view illustrating a hand phantom according to another exemplary embodiment of the present invention;

FIG. 6 is a main part cross-section illustrating a combined state of the hand phantom with a wireless terminal secured therein along the lines 6-6 of FIG. 5;

FIG. 7A is a top plan view of the hand phantom of FIG. 5; and

FIG. 7B is a top plan view of an embodiment variant of the hand phantom of FIG. 5.

### DETAILED DESCRIPTION

Exemplary embodiments of the present invention will be described herein below with reference to the accompanying drawings. In the following description, well-known functions or constructions are not described in detail since they would obscure the invention in unnecessary detail. Terms described below, which are defined considering functions in the various embodiments, can differ depending on user and operator's intent or practice. Therefore, the terms should be understood on the basis of the disclosure throughout this specification.

As used in this document, including the Claims section, the words “a” or “an” mean one or more than one. The term “plurality” means two or more than two. The term “another” is defined as a second or more. The words “comprising”, “including”, “having” and the like are open ended. Reference herein to “one embodiment”, “embodiments”, “an embodiment” or similar term means that a particular feature, structure, or characteristic described in connection with the embodiment is included in at least one embodiment. The appearances of such phrases in various places throughout this disclosure are not necessarily all referring to the same embodiment. Furthermore, the particular features, structures, or characteristics may be combined in any suitable manner on one or more embodiments without limitation. The terms “may” or “can” are used herein to refer to at least an optional element, feature, function, characteristic, advantage, etc., of a described embodiment. Terms such as “substantially” or “generally” signify equality or an approximation with respect to a parameter. For instance, an element said to be “substantially rectangular” or “generally rectangular” means that the element is either perfectly rectangular or is nearly rectangular (e.g., it has rounded edges). The terms “his” and “her” refer to any user.

Herein, the terms “wireless communication terminal”, “wireless terminal” and “terminal” each denote any hand held electronic device capable of transmitting and/or receiving an electromagnetic signal. Examples include cell phones, smart phones, tablet PCs, Personal Digital Assistants (PDAs), smart cameras, and the like. “Applied wireless terminal” refers to a wireless terminal under test for electromagnetic performance, and which is secured by the inventive test fixture.

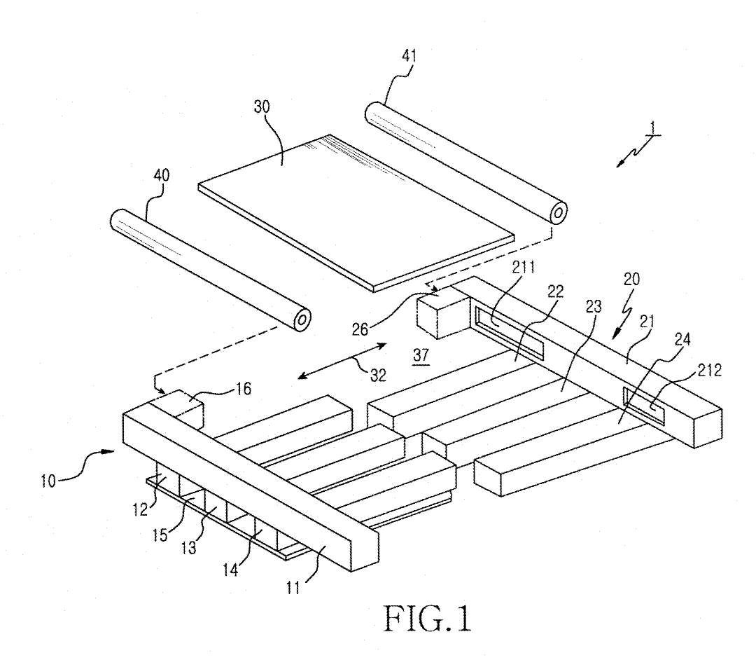

FIG. 1 is an exploded perspective view illustrating a test fixture (hand phantom) 1 according to an exemplary embodiment of the present invention. Herein, the term “test fixture” will be interchangeably referred to as “hand phantom”, since embodiments of text fixtures in accordance with the invention are each configured to simulate a human hand during testing of a wireless communication terminal Hand phantom 1 is constructed to include a 1st dielectric part 10 engaging with a 2nd dielectric part 20 to define an adjustable space 37 between the parts. Thus, wireless communication terminals (not shown in FIG. 1) of various widths can be individually placed within the space 37 for electromagnetic testing. With a terminal placed above the engaging bottom surfaces of parts 10 and 20, side bars 11 and 21 can be adjusted relative to each other as illustrated by direction vector 32. In this manner, the side bars 11 and 21 can be moved against the sides of the terminal to simulate portions of a user's hand and fingers gripping sides of the terminal while the engaged bottom surfaces simulate the user's palm and lower finger portions. The 1st and 2nd dielectric parts 10 and 20 may be composed of a compound of silicon and carbon to meet substantially the same condition as that of a human body, such that the 1st and 2nd dielectric parts 10 and 20 can be formed flexibly to some degree.

As illustrated, the hand phantom 1 includes the 1st dielectric part 10, the 2nd dielectric part 20 coupled with the 1st dielectric part 10 such that space 37 therebetween is adjustable. A plate type spacer 30 is provided to simulate a condition corresponding to an air gap generated between a typical user's palm and a wireless terminal while the user holds the terminal. That is, when the wireless terminal is placed on the top surface of plate spacer 30, the thickness of the spacer 30 separates the bottom surface of the terminal and a combined top surface of interspersed portions of dielectric parts 10, 20. Thus the spacer thickness simulates the air gap.

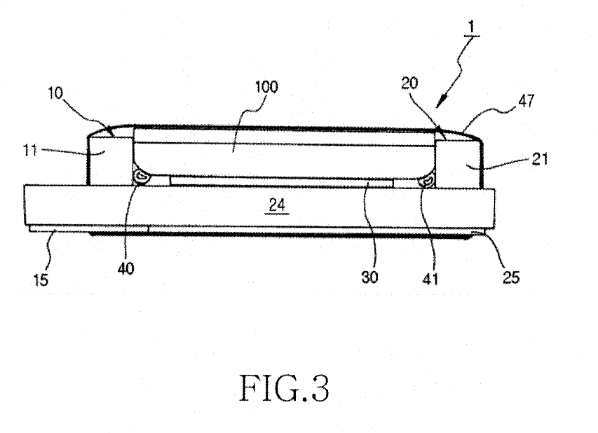

Hand phantom 1 further includes elongated “assistance dielectric parts” 40 and 41 at left and right sides of spacer 30. These assistance dielectric parts 40 and 41 are made of flexible material, allowing the parts to be deformed when the wireless terminal is placed within the test fixture (see FIG. 3). When rounded edges of the wireless communication terminal are applied to vertical edge portions of the respective 1st and 2nd dielectric parts 10 and 20, the assistance dielectric parts 40 and 41 occupy a space between the round edges and the edges of assistance dielectric parts 40 and 41, thereby improving the hand simulation of hand phantom 1.

The 1st dielectric part 10 includes a bar type vertical bar (“first side bar”) 11 of a predetermined length and a plurality of horizontal bars (“first cross bars”) 12, 13, and 14 attached e.g. at constant intervals at a lower surface of the vertical bar 11. The first cross bars 12-14 are oriented transversely to vertical bar 11, e.g., running at right angles to the vertical bar 11.

The 2nd dielectric part 20 includes a bar type vertical bar (“second side bar”) 21 of a predetermined length and a plurality of horizontal bars 22, 23, and 24 (“second cross bars”) attached at constant intervals at a lower surface of the vertical bar 21, oriented transversely, e.g., at right angle to the vertical bar 21.

Accordingly, when the first and second dielectric parts 10, 20 are coupled to each other, the first and second cross bars 12-14 and 22-24 are in a slidably adjustable, interspersed relationship. In this manner, the space 37 between the first and second side bars can be adjusted to accommodate wireless terminals of differing widths, whereby hand phantom 1 is usable as a test fixture for terminals of different sizes.

Stated another way, the horizontal bars 12-14 of the 1st dielectric part 10 are inserted into spaces between the horizontal bars 22-24 of the 2nd dielectric part 20, respectively. In the same condition, the horizontal bars 22-24 of the 2nd dielectric part 20 are inserted into spaces between the horizontal bars 12-14, respectively. Accordingly, the first and second dielectric parts 10 and 20 are installed such that the horizontal bars 12, 13, and 14, and 22, 23, and 24 are arranged while being mutually alternated and guided. In this manner, the space 37 can be adjusted for different sized terminals under test.

Desirably, a 1st additional dielectric part 16 and/or a 2nd additional dielectric part 26 are further attached at one end of each of the side bars 11 and 21 (assumed to be the “far end” of hand phantom 1 in FIG. 1). These additional dielectric parts 16 and 26 are alternatively formed as portions (extensions or protrusions) of the side bars 11 and 12. The additional dielectric dielectric part 16 and/or part 26 function to simulate a user's thumb when the user holds the wireless terminal in his hand.

Further, a plurality of “button recesses” 211 and 212 are formed in each of the side bars 11 and 21, to accommodate buttons protruded from side surfaces of the applied wireless terminal, while major side surfaces of the wireless terminal abut the first and second side bars. By this, the protruded buttons can be prevented from, upon performance testing after terminal mounting, causing an error of performance measurement due to being unintentionally pressed by the side bars 11 and 21.

When hand phantom 1 is manipulated such that cross bars 12-14 substantially interlock with cross bars 22-24, a base mounting surface of the hand phantom 1 is formed as a plane surface with no gap or space such that the terminal can be mounted on the mounting surface of the hand phantom 1. It should be noted, that the number of cross bars can be more or fewer than the three cross bars shown attached to the respective side bars in the figures herein. At a minimum, one cross bar running transversely from each side bar is contemplated to provide a suitable base mounting surface.

The spacer 30 is composed of a material having a low dielectric constant, preferably close to that of air (air has a dielectric constant of 1.0). As such, spacer 30 may be composed of a porous material filled substantially with air, such as a rigid foam-like material. The spacer 30 is formed to have a predetermined thickness and to provide a space between the bottom of the applied terminal and the hand phantom 1 when the spacer 30 is placed atop the mounting surface formed by the coupled dielectric parts 10 and 20. That is, the spacer 30 makes a contribution to more accurate testing of the performance of the wireless communication terminal, by satisfying substantially the same condition as that during actual use in which, when a user holds the terminal in her hand for calling, a rear surface of the terminal and her palm are commonly spaced apart from each other, i.e., an air gap is formed between them.

The assistance dielectric parts 40 and 41 are each in the form of a hollow, deformable cylindrical tube. For example, the cross bars 12-14 and 22-24 and the side bars 11 and 21 are at right angles to one another and form inner edge portions. However, if an applied wireless terminal has rounded edges on its side surfaces, when a user holds the wireless terminal, the rounded edges actually come in contact with the palm. On the other hand, when the wireless terminal is applied to the hand phantom 1 according to the present invention, the rounded edges of the terminal do not come in contact with the angulated inner edge portions of the hand phantom 1 formed by the cross bars and side bars thereof. Accordingly, to address this issue, an embodiment of the present invention includes the assistance dielectric parts 40 and 41. Because these parts 40 and 41 are of a hollow tube type, when the wireless terminal is applied to the hand phantom 1 having the assistance dielectric parts 40 and 41, the parts 40 and 41 are deformed to shapes corresponding to the rounded edges of the wireless terminal (see deformation state in FIG. 3). The resulting contact between dielectric parts 40 and 41 and the round edges of the applied terminal improves the simulation by hand phantom 1 of a human hand holding the terminal.

If cross bars 12-14 and 22-24 are made of a flexible material, instability is possible when interlocked. Accordingly, in an embodiment of the invention, an assistance guide means is provided for ensuring that the cross bars perform a smooth guide operation during sliding adjustment thereof.

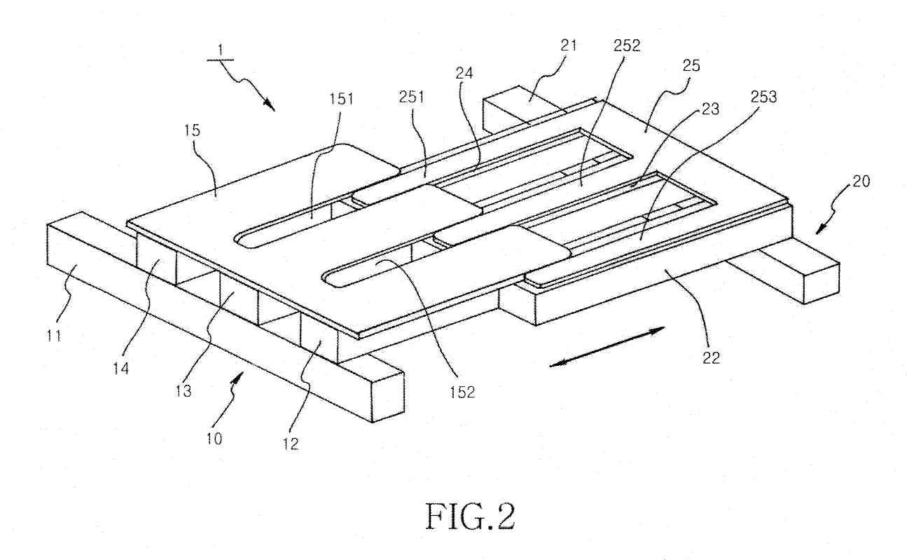

FIG. 2 is a rear perspective view illustrating an assembled configuration of the hand phantom of FIG. 1 according to an embodiment of the present invention. As illustrated, a 1st guide plate 15 is installed on a bottom surface of the 1st dielectric part 10, and a 2nd guide plate 25 is installed on a bottom surface of the 2nd dielectric part 20. The first and second guide plats 15, 25 are provided with interlocking “fingers” that lend support to the cross bars. First guide plate 15 can be provided with surface area sufficient to cover the entire general area of the cross bars 12-14; similarly, second guide plate 25 covers the entire general area of the cross bars 22-24 First guide plate 15 has spaced apart guide slits 151 and 152; second guide plate 25 has guide ribs 251, 252, and 253 arranged on bottom surfaces of the respective cross bars 22, 23, and 24 and capable of being inserted into and guided along the guide slits 151 and 152. Accordingly, as cross bars 12-14 and cross bars 22-24 are mutually alternated and guided, the guide ribs 251, 252, and 253 are correspondingly inserted into and guided along the guide slits 151 and 152.

The cross bars 12-14 and 22-24 can be all attached and fixed to the first and second guide plates 15 and 25, respectively. This structure is advantageous in assisting a guide operation and concurrently supporting the 1st and 2nd dielectric parts 10 and 20 if composed of flexible materials. That is, the relatively rigid guide plates are fixed to bottom surfaces of the 1st and 2nd dielectric parts 10 and 20 composed of flexible materials, thereby stabilizing the overall structure.

FIG. 3 is an end view of the hand phantom 1 of FIGS. 1 and 2, illustrating a state in which a wireless communication terminal for performance testing is mounted therein. Prior to placing the wireless terminal 100 within hand phantom 1, the cross bars 12-14 the cross bars 22-24 are mutually alternated and guided, whereby a spacing between the side bar 11 and the side bar 21 is adjusted. In this position, the wireless terminal is placed on the mounting surface of the hand phantom 1 formed by the horizontal bars 12-14 and 22-24 and then the side bars 11 and 21 are pulled in or pushed out reciprocally. Thereby, the side bars 11 and 21 come in tight contact with side surfaces of the wireless terminal (e.g. left and right side surfaces of a terminal with generally solid rectangular or square form factor).

After the spacer 30 is placed on the mounting surface of the hand phantom 1 formed by the cross-guided horizontal bars 12-14 and 22-24, the wireless terminal side edges are placed on the spacer 30. As mentioned earlier, spacer 30 simulates an air space between the palm and a bottom surface of the wireless communication terminal when a user actually holds the wireless communication terminal with his hand. The spacer 30 thus renders more accurate performance measurement possible.

Further, if bottom edges of the wireless communication terminal are rounded off, as seen in FIG. 3, the assistance dielectric parts 40 and 41 according to the present invention are interposed in the corners between the side bars and cross bars, i.e., in the inner edge portions formed by the horizontal bars 12-14 and 22-24 and the vertical bars 11 and 21. Thereby, the assistance dielectric parts 40 and 41 can come in contact with the rounded bottom edges of the wireless terminal and become compressed thereby.

As illustrated, after the spacer 30 and the assistance dielectric parts 40 and 41 according to embodiments of the present invention are interposed onto parts 10 and 11, the wireless communication terminal is mounted on the spacer 30 and the assistance dielectric parts 40 and 41. In this condition, the spacer 30 can provide a gap of a predetermined space at the bottom surface of the wireless communication terminal, and the assistance dielectric parts 40 and 41 can come in contact with the rounded edges of the wireless communication terminal, thereby accurately simulating a state in which the user actually holds the wireless communication terminal with her hand. After that, finally, the wireless terminal is securely fastened to hand phantom 1 by an elastic coupling means 47, for example, at least one rubber band or the like, which prevents separation. An electromagnetic performance test for the wireless communication terminal secured by hand phantom 1 may then be carried out.

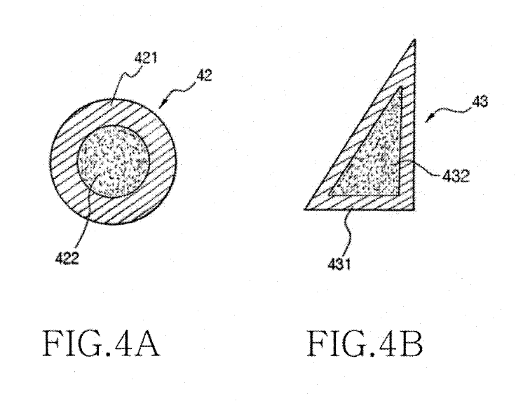

FIGS. 4A and 4B are cross sectional views illustrating respective shapes of assistance dielectric parts according to exemplary embodiments. As shown in FIG. 4A, an assistance dielectric part 42 includes a tube type dielectric part 421 having a circular cross section. A fluid 422 fills a hollow interior of the tube type dielectric part 421. In alternative configurations, fluid is omitted.

In the embodiment of FIG. 4B, an assistance dielectric part 43 includes a tube type dielectric part 431 (elongated with hollow interior) having a cross section in the shape of a right triangle, and a fluid 432 filled in the hollow interior of tube type dielectric part 431. In an alternative design, fluid is omitted. Further, other shapes are possible. For instance, shapes of assistance dielectric parts can be designed specifically tailored to the shapes of edges of the applied wireless terminals.

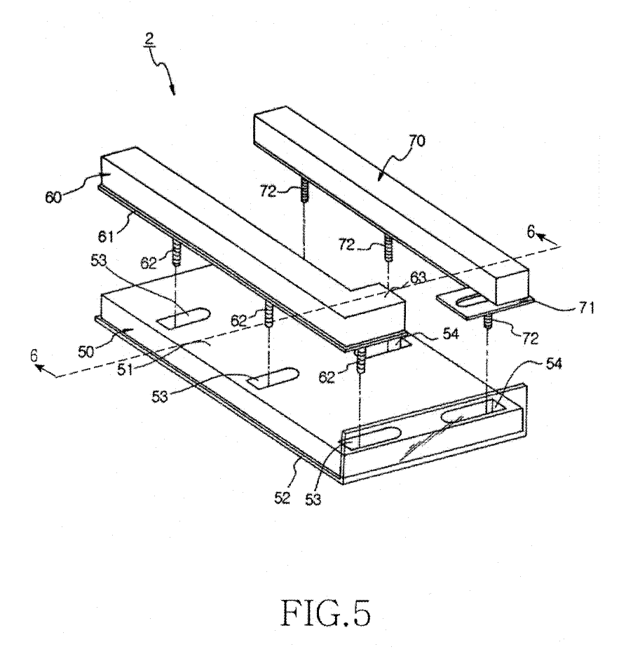

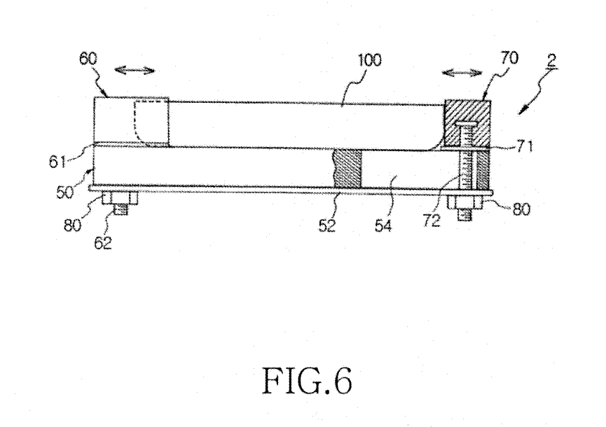

FIG. 5 is an exploded perspective view illustrating a hand phantom 2 according to another exemplary embodiment of the present invention. FIG. 6 is a main part cross-section along the lines 6-6 of FIG. 5 illustrating a combined state of the hand phantom 2 of FIG. 5 securing a wireless terminal.

Referring to FIG. 5 and FIG. 6, the hand phantom 2 includes 1st and 2nd dielectric side bars 60 and 70 which can be similar to the side bars 11 and 21 of FIG. 1. A plate type 3rd dielectric part 50 is provided for guiding the 1st and 2nd dielectric parts 60 and 70 and supporting a bottom surface of an applied wireless communication terminal 100.

Accordingly, the 1st and 2nd dielectric parts 60 and 70 perform a role of closely supporting both side surfaces of the wireless communication terminal 100 which is placed on a top surface 51 of the 3rd dielectric part 50. Also, the 1st and 2nd dielectric parts 60 and 70 make mutual spacing adjustment possible and therefore, the 1st and 2nd dielectric parts 60 and 70 can be fixed in position after coming in contact with both side surfaces of the applied wireless communication terminal 100.

Because the 1st, 2nd, and 3rd dielectric parts 60, 70, and 50 are dielectric parts of flexible carbon material as in the embodiment described above (e.g., compound of silicon and carbon), predetermined guide plates 61, 71, and 52 are installed to support bottom surfaces of the 1st, 2nd, and 3rd dielectric parts 60, making a guide operation smoother.

The plate type 3rd dielectric part 50 has a plurality of guide through-holes 53 and 54 spaced apart at constant intervals. The guide through-holes 53 and 54 are provided to penetrate a top surface 51 of the 3rd dielectric part 50 to a bottom surface thereof, and have predetermined lengths of the width direction of the 3rd dielectric part 50 for the sake of adjustment of an interval between the 1st and 2nd dielectric parts 60 and 70. In the drawings, three guide through-holes 53 are provided at constant intervals to guide the 1st dielectric part 60 and three guide through-holes 54 are provided at constant intervals to guide the 2nd dielectric part 70, respectively. It is desirable that the guide through-holes 53 and 54 are provided in positions exerting no influence on the radiation performance of the applied wireless communication terminal 100. In detail, it is preferable to arrange the guide through-holes 53 and 54 in positions away from an RF connector within the wireless communication terminal 100 at a time the wireless communication terminal 100 is mounted.

Bolts 62 and 72 are installed in the 1st and 2nd dielectric parts 60 and 70 to protrude downward in positions corresponding to the guide through-holes 53 and 54. The bolts 62 and 72 can be partially fixed to the 1st and 2nd dielectric parts 60 and 70 in an insert-molding scheme.

As illustrated in FIG. 6, when the 1st and 2nd dielectric parts 60 and 70 are arranged on the top surface 51 of the 3rd dielectric part 50, the bolts 62 and 72 thereof pass through the corresponding guide through-holes 53 and 54 of the 3rd dielectric part 50 and protrude outside a bottom side of the 3rd dielectric part 50, respectively. Nuts 80 can engage with the down-protruded bolts 62 and 72 and fix the 1st and 2nd dielectric parts 60 and 70 to the 3rd dielectric part 50. It is desirable that the bolts 62 and 72 and the nuts 80 are formed of non-conductive material in consideration of influence that is exerted on the wireless communication terminal 100 when the hand phantom 2 secures terminal 100 during performance testing. More desirably, the bolts 62 and 72 and the nuts 80 can be formed of synthetic resin material.

While not shown in FIGS. 5 and 6, a spacer 30 and assistance dielectric parts such as 40, 41 or 43 can be employed in hand phantom 2 in the same manner as described above for the hand phantom 1 of FIGS. 1-3. In this case spacer 30 and the assistance dielectric parts would be placed atop surface 51 prior to placing the wireless terminal 100 within hand phantom 2.

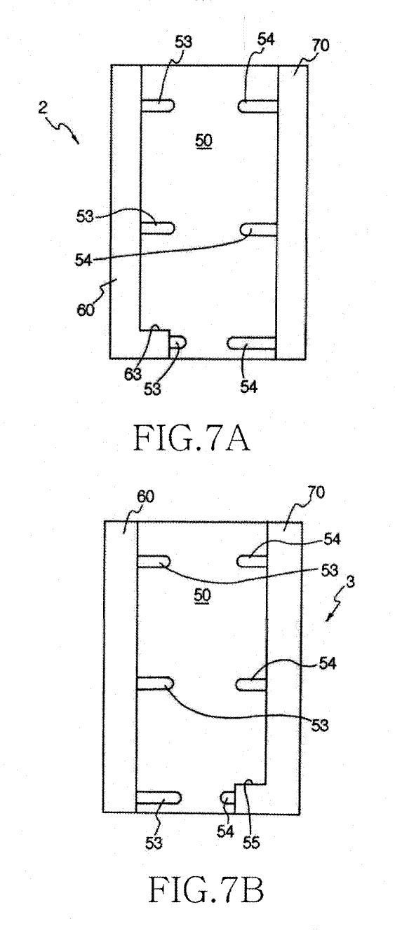

FIG. 7A is a top plan view of the hand phantom 2 of FIG. 5. FIG. 7B is an embodiment variant of the hand phantom 2 of FIG. 5. As illustrated in FIGS. 7A and 7B, hand phantoms 2 and 3 are for measuring influence that is exerted on an antenna radiation characteristic of a wireless terminal when a user actually holds the wireless terminal in his hand. Accordingly, to simulate this situation more accurately, additional dielectric parts 63 and 55 are formed to extend from lower sides of the 1st and 2nd dielectric parts 60 and 70 toward the counterpart dielectric parts 70 and 60. The additional dielectric parts 63 and 55 are for simulating a thick palm portion between the thumb finger and the wrist as a user holds the wireless terminal, and can be helpful for more accurately testing the radiation performance of the terminal 100.

FIG. 7A illustrates the assistance dielectric part 63 bent from the lower side of the 1st dielectric part 60 toward the 2nd dielectric part 70. This case is for simulating a state in which the user holds the wireless communication terminal 100 with her left hand.

FIG. 7B is a plan view illustrating an alternative embodiment, 3, of the hand phantom of FIG. 5. Hand phantom 3 is configured to simulate a user's right hand holding a wireless terminal. As such, an additional dielectric part 55 extends bent from the lower portion of right bar 70 to simulate a portion of the use's right hand, and the additional dielectric part 53 is omitted from left bar 60.

As described above, since hand phantoms (test fixtures) according to embodiments of the present invention are adjustable in size, there is an effect that the user can test wireless communication terminals of various shapes and sizes by the same hand phantom. Since hand phantoms according to the present invention provide substantially the same condition as that when the user holds the wireless communication terminal with his or her hand, there is an effect that the hand phantom can prevent an additional cost incurred by manufacturing of many different designs of hand phantoms and can lead to reliable testing of wireless communication terminals.

While the invention has been shown and described with reference to certain preferred embodiments thereof, it will be understood by those skilled in the art that various changes in form and details may be made therein without departing from the spirit and scope of the invention as defined by the appended claims

What is claimed is:

1. A test fixture with hand simulation for securing a wireless terminal during a performance test, the test fixture comprising:
first and second dielectric parts adjustably spaced apart to adjust a distance of a testing space therebetween within which the wireless terminal is securable;
wherein the testing space is adjusted according to a size of the wireless terminal by adjusting a distance between portions of the first and second dielectric parts.

2. The test fixture of claim 1, wherein the first dielectric part comprises:
a first side bar of a predetermined length; and
at least one first cross bar oriented transversely at a right angle to the first side bar and disposed at a lower surface thereof,
the second dielectric part comprises:
a second side bar of a predetermined length; and
at least one second cross bar oriented at a right angle to the second side bar and disposed at a lower surface thereof;
wherein the at least one first and second cross bars are reciprocally guided to provide the testing space.

3. The test fixture of claim 2, wherein the at least one first cross bar comprises at least two first cross bars, the at least one second cross bar comprises at least two second cross bars, wherein the at least two first cross bars are interspersed with the at least two second cross bars while being reciprocally guided without a gap.

4. The test fixture of claim 2, wherein the side bars of the first and second dielectric parts each have formed therein at least one button recess within which a protruding button of a wireless terminal under test is housed while major side surfaces of the wireless terminal abut the first and second side bars.

5. The test fixture of claim 2, further comprising an additional dielectric part for simulating a user's thumb while holding the wireless terminal, the additional dielectric part being extending in a transverse direction to the first and second side bars.

6. The test fixture of claim 2, further comprising first and second guide plates attached to lower surfaces of the 1st and 2nd dielectric parts, respectively, and the first and second guide plates configured to assist a reciprocal guide operation of the 1st and 2nd dielectric parts.

7. The test fixture of claim 6, wherein the 1st guide plate has at least one guide slit, and the 2nd guide plate has at least one guide rib inserted into and guided along the at least one guide slit.

8. The test fixture of claim 1, further comprising a spacer of a predetermined thickness and width, interposed in the testing space to simulate an air gap between the wireless terminal and a user's palm when the terminal is in a hand held state.

9. The test fixture of claim 2, further comprising a spacer of a predetermined thickness and width, interposed in the testing space to simulate an air gap between the wireless terminal and a user's palm when the terminal is in a hand held state.

10. The test fixture of claim 1, further comprising at least one assistance dielectric part interposed in the housing space to come in contact with rounded edges of an applied wireless terminal.

11. The test fixture of claim 2, further comprising at least one assistance dielectric part interposed in the housing space in an inner edge portion formed by the cross bars of the 1st and 2nd dielectric parts and the side bars thereof to come in contact with rounded edges of an applied wireless terminal.

12. The test fixture of claim 11, wherein the assistance dielectric part is a hollow tube type dielectric part of substantially the same length as the first or second side bar.

13. The test fixture of claim 12, wherein a hollow portion of the assistance dielectric part is filled with a fluid.

14. The test fixture of claim 12, wherein the assistance dielectric part is configured having a cross section in the shape of a circle, oval, right triangle, or polygon.

15. The test fixture of claim 1, further comprising a coupling means for firmly securing the wireless terminal in the housing space.

16. The test fixture of claim 15, wherein the coupling means comprises at least one rubber band for winding all of the 1st and 2nd dielectric parts and the wireless terminal together.

17. The test fixture of claim 1, further comprising a plate type 3rd dielectric part upon which the first and second dielectric parts are disposed, the third dielectric part coming in contact with a bottom surface of an applied wireless terminal and simulating a user's palm.

18. The test fixture of claim 17, wherein the 1st dielectric part and the 2nd dielectric part are formed in a bar shape having a length substantially the same as a length in a longitudinal direction of the plate type 3rd dielectric part, and
further comprising a guide plate installed at a bottom surface of the each of the first and second dielectric parts to assist guidance.

19. The test fixture of claim 17, wherein,
the plate type 3rd dielectric part comprises at least one pair of guide through-holes formed therein at constant intervals;
non-conductive bolts of predetermined lengths are installed to protrude downward from bottom surfaces of the 1st and 2nd dielectric parts, and
the bolts are coupled with predetermined non-conductive nuts after passing through the guide through-holes, thereby fixing positions of the 1st and 2nd dielectric parts.

20. The test fixture of claim 17, wherein an additional dielectric part for simulating a palm portion between a user's thumb and wrist when a user holds the terminal is formed to be bent toward a counterpart dielectric part in either the first or second dielectric parts.
